(19) United States
(12) Patent Application Publication
(10) Pub. No.: US 2026/0133252 A1
(43) Pub. Date: May 14, 2026

(54) METHOD TO OPTIMIZE THE BATTERY USAGE OF A SMART KEY

(71) Applicant: Renesas Electronics Corporation, Tokyo (JP)

(72) Inventors: Stephan Johannes RENNER, Haan (DE); Soeren Robert SAPPOK, Duisburg (DE); Leonardo Jose Mendes RIBEIRO, Ratingen (DE); Abdelfattah Fawky Abdelfattah Soliman Megahed, Bochum (DE)

(73) Assignee: Renesas Electronics Corporation, Tokyo (JP)

(21) Appl. No.: 18/941,438

(22) Filed: Nov. 8, 2024

(51) Int. Cl. G01R 31/382; G06F 1/16; G07C 9/00

(52) U.S. Cl. CPC G01R 31/382; G06F 1/163; G07C 9/00309

(57) ABSTRACT

A System of a wearable device powered by a battery and built to emit a digital pulse signal and a static device built to process a multilateration of the wearable device, wherein the static device comprises:
at least two receivers, both built to receive the digital pulse signal with a time difference caused by their individual distance to the wearable device;
a multilateration stage built to process a multilateration of the wearable device based on the time difference between the two received digital pulse signals;
a static device communication stage built to communicate commands and/or data with the wearable device,
   and wherein the wearable device comprises:
a transmitter stage built to transmit the digital pulse signal composed of several ranging rounds, each with a sequence of digital pulses, and sleep mode periods without digital pulses between the ranging rounds,
   which wearable device comprises:
a measurement stage built to measure a current provided by the battery of the wearable device to a capacitor of the wearable device, which capacitor is dimensioned that its capacitor load of the fully charged capacitor powers the wearable device during one ranging round;
a determination stage built to determine a charge time needed to fully charge the capacitor until the end of the sleep mode period based on the capacitor size and the measured current;
a wearable device communication stage built to communicate a request for a minimum extended time slot duration with the static device communication stage to fully charge the capacitor with the measured current until the end of each sleep mode period, if the determined charge time needed is longer than the duration of the sleep mode period between ranging rounds.

### FIELD OF THE INVENTION

The present invention relates to a method and system that enables multilateration and/or distance measurement of a wearable device by a static device to open a door of the static device, while the battery usage of the wearable device is optimized.

### BACKGROUND OF THE INVENTION

Specification “Car Connectivity Consortium—Digital Key Release 3” (Technical Specification Version 1.2.3 (CCC-TS-101)) discloses such a method and system that enables a multilateration and/or distance measurement of a smart key (wearable device) to open a door of a vehicle (static device). This specification standardizes how to prevent illegal access to the vehicle, by verifying the identity and proximity of the user. It discloses a method to calculate the distance between the vehicle and the user that wears the smart key using UWB (Ultra-Wideband) to ensure that the user is within a few meters of the vehicle.

The vehicle comprises at least two receivers to receive an UWB digital pulse signal from the smart key and multilateration stage to use the time difference of these received signals to calculate the distance between the vehicle and the smart key. A static device communication stage comprises a BLE stage (Bluetooth Low Energy), which is used to communicate commands and/or data with the smart key. While the vehicle anchors are powered by a vehicle battery, the smart key is typically powered by a lithium-based coin cell (e.g., CR2450 type) which has a limited capacity and furthermore also an unloaded voltage level, which depends on the state of charge and an internal resistance which depends on the temperature and other factors.

FIG. 1 shows such a state-of-the-art smart key 1 using a CR2450 lithium battery as coin cell 2 to power the smart key 1. An NFC stage 3 (Near Field Communication) with its secure element 4 is used to enable an identification of an entitled user of the vehicle. NFC technology has been developed by an industry consortium under the name of NFC Forum (http://www.nfc-forum.org) and derives from RFID technology. A transmitter stage of the smart key 1 comprises an UWB stage 5 to transmit the UWB digital pulse signal and a wearable device communication stage comprises a BLE stage 6 to setup the authentication and configuration exchange between the smart key 1 and the vehicle. NFC stage 3 and secure element 4 are directly connected with and supplied by the coin cell 2, while UWB stage 5 and BLE stage 6 are powered by the coin cell 2 via a buffer capacitor 7.

The current drawn from the coin cell 2 is limited to a reasonable value by a current limiter 8 to maximize the amount of charge which can be drawn from the coin cell 2 until its battery voltage level drops to a level which cannot be used anymore. The size of the buffer capacitor 7 is chosen such that it can supply the UWB stage 5 and potentially also the BLE stage 6 for one complete ranging round of the UWB digital pulse signal without the voltage level dropping below a reset voltage threshold VR (e.g., 1.8 V) of either the UWB stage 5 or the BLE stage 6. Thus, recharging of the buffer capacitor 7 takes place during a sleep mode period of the UWB digital pulse signal as will be explained based on FIG. 2.

FIG. 2 shows an UWB digital pulse signal 9 emitted by the UWB stage 5 to enable distance measurement in the vehicle. Smart key 1 emits multiple sets of ranging frames 10, wherein the time between each frame in the set may be defined as a time slot 11 with a time slot duration t_{S}. Each set of ranging frames 10 may be defined as a ranging round 12. The number of ranging frames 10 in each ranging round 12 is defined in the above referenced specification as a fixed number and defined during the initial BLE communication. When UWB stage 5 is in a transmit mode 13 the ranging frame 10 is transmitted and energy is consumed by the smart key 1. When UWB stage 5 is in an idle mode 14, between ranging frames 10, less energy is consumed, but still not an insignificant amount, as the smart key 1 needs to maintain precise timing for the rest of the transmissions.

Reducing the time that UWB stage 5 is in idle mode 14 allows to save power in the smart key 1 due to the following reason. The ranging frames 10 are transmitted faster, allowing the process to be completed faster with less time spent in idle mode 14. However, it is possible that the vehicle may not be able to support shorter time slots 11. Hence why during the original handshake there is a negotiation between the static device communication stage of the vehicle and the wearable device communication stage of the smart key 1 for the duration of the time slot 11.

The time between ranging rounds 12 is called sleep mode period 15 and is defined by the above referenced specification and may for instance have a duration of 288 ms. Between ranging rounds 12, during sleep mode periods 15, there is still some energy used, but it is much less compared to idle mode 14 within the ranging round 12.

Coin cell 2 has a different performance depending on its temperature and state of charge, because its internal electrolytic contents affect its internal resistance. Thus, for extreme cases (e.g. when the battery is exhausted) the current output may be even smaller than the limit imposed by the current limiter 8. The difference in performance depending on the capacity and temperature of the coin cell 2 can be seen in FIG. 3 with a new coin cell 2 at room temperature. Buffer capacitor voltage V1, measured at the pins of the buffer capacitor 7, reduces during a ranging round 12, but never drops below the reset voltage threshold VR of either UWB stage 5 or BLE stage 6. During sleep mode 15 buffer capacitor 7 is recharged for the next ranging round 12. A second buffer capacitor voltage V2 with an exhausted coin cell 2 at low temperature has lower voltages and comes closer to the reset voltage threshold VR at the end of the ranging round 12 where the smart key 1 seizes to send ranging frames 10 of UWB digital pulse signal 9.

It would be beneficial to improve the battery lifetime of the state-of-the-art smart key, which means extending the time until the buffer capacitor voltage at the end of the ranging rounds reduces to or below the reset voltage threshold VR and the smart key 1 stops working.

### SUMMARY OF THE INVENTION

It is an object of the invention to provide a method and a system with a smart key that uses less power of the coin cell and enables a longer lifetime of the smart key.

This objective is achieved with a method as claimed in claim 1 and a system as claimed in claim 8. It has become clear that the current provided by the battery or coin cell via the current limiter to the buffer capacitor, which depends on the exhaustion of the coin cell and the temperature, is the relevant factor to determine the time slot duration of the UWB digital pulse signal of the smart key. This current is measured and the charge time needed is determined to fully charge the buffer capacitor until the beginning of the next ranging round. The capacity of the buffer capacitor is of course a relevant factor in this determination. In case the charge time needed is longer than the sleep mode period between ranging rounds, which is defined by the initial ranging session configuration exchange based on the “Car Connectivity Consortium—Digital Key Release 3” specification, an extended time slot duration is agreed between the smart key and the vehicle to ensure that the buffer capacitor is fully charged at the end of each sleep mode period. This extension of the time slot duration is kept as minimal as possible to still ensure that only a small amount of energy is used in the smart key which extends its battery lifetime.

To further extend the battery lifetime of the smart key it is advantageous to not only consider the duration of the sleep mode period, but in addition the duration of the ranging rounds, and in particular the duration of one or all the idle modes of the ranging round, to charge the buffer capacitor. This means that charge loaded into the buffer capacitor by the measured current provided during idle modes of one ranging round is added to the charge loaded into the buffer capacitor by the measured current during the sleep mode period. This helps to fully load the buffer capacitor with less current provided by the already exhausted coin cell or at temperatures less favorable for the coin cell.

It is furthermore advantageous to measure the temperature in the smart key and use the measured temperature for the determination of the charge time needed and the time slot duration of the digital pulse signal. The determination is even more accurate, if the charge in the buffer capacitor and/or the buffer capacitor voltage left at the end of the ranging round is taken into account, when the charge time needed is determined. Therefore, the extension of the time slot duration may be reduced and kept minimal. This further extends the lifetime of the coin cell as less peak current from the coin cell is needed to fully load the at the end of the ranging round for instance still half loaded buffer capacitor.

These and other aspects of the invention will be apparent from and elucidated with reference to the embodiments described hereinafter. The person skilled in the art will understand that various embodiments may be combined.

### BRIEF DESCRIPTION OF THE DRAWINGS

FIG. 1 shows the architecture of a smart key according to the state of the art.

FIG. 2 shows a digital pulse signal emitted by the smart key of FIG. 1 to enable a vehicle to measure the distance between the smart key and the vehicle.

FIG. 3 shows the difference in performance of a coin cell used in the smart key of FIG. 1, which depends on its state of charge and temperature.

FIG. 4 shows a block diagram of a system of a smart key and a vehicle according to a first embodiment of the invention.

FIG. 5 shows a digital pulse signal emitted by the smart key of FIG. 4 to enable the vehicle to measure the distance between the smart key and the vehicle.

FIG. 6 shows a flow diagram of steps of a method processed by the system of FIG. 4.

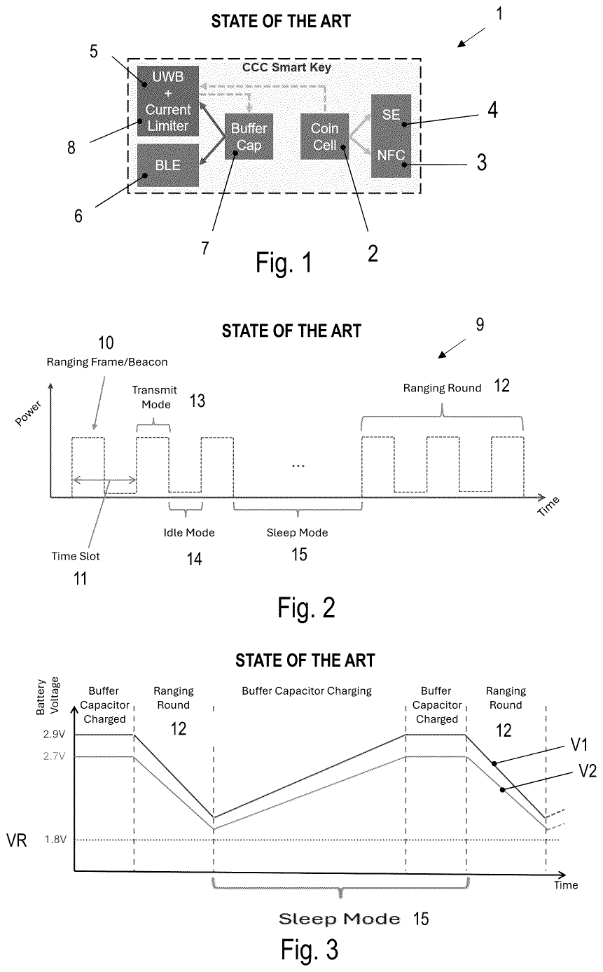

### DETAILED DESCRIPTION OF EMBODIMENTS

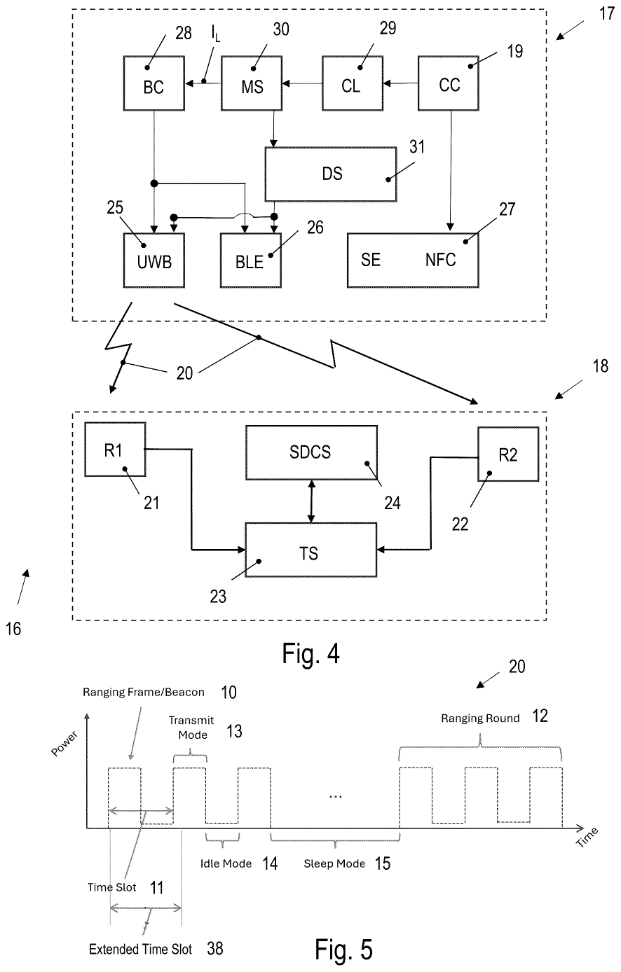

FIG. 4 shows a system 16 of a wearable device, realized as a smart key 17, and a static device, realized as a car 18, built to process a multilateration of the smart key 17 to determine the distance between the smart key 17 and the car 18. Smart key 17 is powered by a coin cell 19 and built to emit an UWB digital pulse signal 20 shown in FIG. 5, as defined in the “Car Connectivity Consortium—Digital Key Release 3” specification and with its principial content of ranging rounds 12 with ranging frames 10 and sleep mode periods 15, as explained in relation to FIG. 2.

Block diagram of FIG. 4 only shows blocks relevant to explain the embodiment of the invention, all other blocks and functions not directly linked to the invention are not mentioned, but a skilled person could add them as needed. Car 18 comprises two UWB receivers 21 and 22, both built to receive the UWB digital pulse signal 20 with a time difference caused by their individual distance to the smart key 17. Car 18 furthermore comprises a multilateration stage 23, built to process the calculation for a multilateration of the smart key 17 based on the time difference between the two received UWB digital pulse signals 20. Car 18 furthermore comprises a static device communication stage 24 to communicate via Bluetooth Low Energy and/or via NFC commands and/or data with the smart key 17 to enable an authorized user to open the door of car 18. A person skilled in the art is aware how this has to be implemented, for instance based on the specification “Car Connectivity Consortium—Digital Key Release 3”.

Smart key 17 comprises a transmitter stage realized as UWB stage 25, built to transmit the UWB digital pulse signal 20 as shown in FIG. 5 and composed of several ranging rounds 12, each with a sequence of ranging frames 10, and sleep mode periods 15 without ranging frames 10 between the ranging rounds 12. The transmitter stage is built to transmit the digital pulse signal in the 3.1 GHz to 10.6 GHz band, which frequency band is used by Ultra-Wideband. In this embodiment of the invention, the sleep mode periods 15 are fixed with a duration of 300 ms, but there are other embodiments possible where other durations might be fixed or the sleep mode period 15 might be changed as well as agreed between the smart key 17 and the car 18. Furthermore, in this embodiment of the invention the number of ranging frames 10 in one ranging round 12 is fixed with 10 ranging frames 10, but there are other embodiments possible where a different number of ranging frames 10 in one ranging round 12 might be defined. The number of receive frames depends on the actual number of cars that anchor and transmit the UWB digital pulse signal 20 in response to an initial transmit signal from the smart key 17.

Smart key 17 furthermore comprises a wearable device communication stage realized as a BLE stage 26 and an NFC stage 27, including a secure element for authentication, to enable data communication via Bluetooth Low Energy of the smart key 17 with the static device communication stage 24 of the car 18. NFC stage 27 is directly powered by coin cell 19, while UWB stage 25 and BLE stage 26 are powered by a buffer capacitor 28 charged by coin cell 19, which is dimensioned that its capacitor load of the fully charged buffer capacitor 28 powers the smart key 17 during at least one ranging round 12. This means that the size of the buffer capacitor 28 is chosen such that it can supply UWB stage 25 and also the BLE stage 26 for one complete ranging round 12 of the UWB digital pulse signal 20 without the voltage level dropping below the reset voltage threshold VR (e.g., 1.8 V) shown in FIG. 3 of either of the UWB stage 25 or the BLE stage 26. A different embodiment can be implemented such that the BLE stage 26 is directly connected to the battery and the UWB stage 25 is the only part powered by the buffer capacitor. The current drawn from the coin cell 19 to charge the buffer capacitor 28 is limited to a reasonable value by a current limiter 29 to increase the amount of charge which can be drawn from the coin cell 19 until its battery voltage level drops below the reset voltage threshold VR which cannot be used anymore to the power smart key 17.

The smart key 17 furthermore comprises a measurement stage 30 built to measure a current I_{L} provided by the coin cell 19 of the smart key 17 to the buffer capacitor 28. In case the battery voltage and internal resistance of the coin cell 19 are sufficient to supply the value configured for the current limiter 29, then the current limiter 29 will output the specified limited current I_{L}. In case the battery voltage and internal resistance of the coin cell 19 are insufficient to fully supply the current limiter 29 as specified, then the current limiter 29 will output a lower than specified limited current I_{L}. Measurement stage 30 will in both cases measure the current I_{L} that actually provides load into buffer capacitor 28, what increases its accuracy for the following described calculation. In another embodiment of the invention the measurement stage could be positioned between the coin cell and the current limiter to measure the current drawn from the coin cell.

Smart key 17 furthermore comprises a determination stage 31, built to determine a charge time t_{C} needed to fully charge the buffer capacitor 28 from empty to fully charged until the end of the sleep mode period 15 based on the capacitor size and the measured current I_{L} provided to the buffer capacitor 28. A person skilled in the art is able to calculate the charge time t_{C} needed taking the assumption that the buffer capacitor 28 is completely unloaded and needs to be fully loaded.

In a preferred embodiment of the invention the determination stage 31 is built to take the capacitor load or capacitor voltage left in the buffer capacitor 28 at the end of the ranging round 12 into account for the determination of the charge time t_{C} needed to fully charge buffer capacitor 28 until the end of the sleep mode period 15. This enables a very accurate determination of the charge time t_{C} needed for a small measured current I_{L}, if the coin cell 19 is already exhausted.

In a further preferred embodiment of the invention the measurement stage 30 is built to measure the actual temperature in the smart key 17 and the determination stage 31 is built to take the measured temperature into account when determining the charge time t_{C} needed. As the performance of the coin cell 19 depends on the temperature, this determination of the charge time t_{C} needed is even more accurate.

In one embodiment of the invention (version 1) buffer capacity 28 is only loaded during sleep mode periods 15 between ranging rounds 12. In a further best mode embodiment (version 2) buffer capacitor 28 is not only charged with the measured current I_{L} during the sleep mode period 15, but in addition during idle mode periods 14 in between the transmission of ranging frames 10 in ranging rounds 12. This increases the effective time to charge the buffer capacitor 28 and enables to have the buffer capacitor 28 fully charged at the end of the sleep mode period 15 even with a smaller measured current I_{L} provided by a more exhausted coin cell 19, what extends the lifetime of the smart key 17 with coin cell 19.

Smart key 17 with its UWB stage 25 or with its BLE stage 26 is furthermore built to communicate a request for a minimum extended time slot duration 38 with the static device communication stage 24, if the determined charge time t_{C} needed is longer than the sleep mode period 15 (version 1) or longer then the sleep mode period 15 together with one or all idle mode periods 14 (version 2), to fully charge the buffer capacitor 28 with the measured current I_{L} until the end of each sleep mode period 15. The time slot duration 11 is one of the parameters that are free to negotiate based on the specification “Car Connectivity Consortium—Digital Key Release 3”. There are some pre-defined options for the time slot duration 11 like 1.33 ms or 2 ms, however non-standard values are also possible what is used for this invention like for example 3 ms.

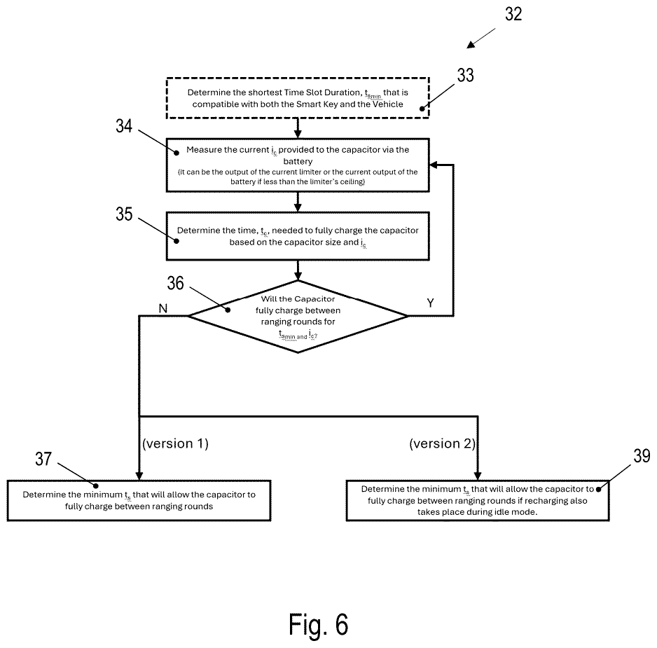

FIG. 6 shows a flow diagram of steps of a method 32 processed by the smart key 17 and the car 18 of FIG. 4. In a first step 33 of the method 32 the shortest time slot duration t_{Smin} as initial time slot duration is determined in a communication between the smart key 17 and the car 18. This is essential as not all car anchor 18 support short time slot duration t_{S}. The shorter the time slot duration t_{S} is set, the shorter the transmit modes 13 of the ranging frames 10 are, because the number of ranging frames 10 in a ranging round 12 is fixed. This saves energy and extends the lifetime of coin cell 19.

In a second step 34 measurement stage 30 measures the current I_{L} provided by the coin cell 19 of the smart key 17 to the buffer capacitor 28 of the smart key 17, which buffer capacitor load of the fully charged buffer capacitor 28 powers the smart key 17 during one ranging round 12.

In a third step 35 the determination stage 24 determines the charge time t_{C} needed to fully charge the buffer capacitor 28 until the end of the sleep mode period 15 based on the size of the buffer capacitor 28 and the measured current I_{L}.

In a fourth step 36 the determination stage 24 decides, if the buffer capacitor 28 will be fully charged with the measured current I_{L} between ranging rounds 12 until the end of each sleep mode period 15. If that is the case, method 32 is further processed with the second step 34 as shown in FIG. 6. If in the other case the determined charge time t_{C} needed is longer than the duration of the sleep mode period 15 between ranging rounds 12, method 32 will proceed with a fifth step 37 (version 1) to agree a minimum extended time slot duration 38 with the car 18. As explained above, the time slot duration 11 shall be as short as possible to keep the transmit modes 13 short to extend the lifetime of coin cell 19. Therefore, the minimum extended time slot duration 38 is agreed on between the smart key 17 and car 18 in that way that it is ensured that buffer capacitor 28 will be fully charged with the measured current I_{L} until the end of each sleep mode period 15 and that still this minimum extended time slot duration 38 still enables a long lifetime of the coin cell 19.

In the above explained best mode embodiment not only the sleep mode period 15, but in addition at least one, but best all idle mode periods 14 of the ranging round 12 are used to charge the buffer capacitor 28. For this best mode embodiment, if in the fourth step 36 it is decided that the determined charge time t_{C} needed is longer than the duration of the sleep mode period 15 and at least one, but best all idle mode periods 14 of the ranging round 12, method 32 will proceed with a sixth step 39 (version 2) to agree on a minimum extended time slot duration 38 with the car 18. This minimum extended time slot duration 38 is agreed on between the smart key 17 and car 18 in this best mode embodiment to ensure that the buffer capacitor 28 will be fully charged with the measured current I_{L} until the end of each sleep mode period 15 taking the sleep mode period 15 and at least one, but best all idle mode periods 14 of the ranging round 12 as charge time into account. This means that the need to extend the time slot duration in this best mode embodiment will be less than in the above-mentioned embodiment and the lifetime of the coin cell 19 in this best mode embodiment will be longer.

1. Method for changing a time slot duration of digital pulses in a digital pulse signal emitted by a wearable device, which digital pulse signal enables a multilateration of the wearable device by a static device, which digital pulse signal is composed of several ranging rounds, each with a sequence of digital pulses, and sleep mode periods without digital pulses between the ranging rounds, which method comprises the following steps processed in the static device:
Measure a time difference between the digital pulse signals received with at least two receivers in the static device to enable multilateration of the wearable device;
which method comprises the following steps processed recurring in the wearable device:
Measure a current provided by a battery of the wearable device to a capacitor of the wearable device, which capacitor load of the fully charged capacitor powers the wearable device during one ranging round;
Determine a charge time needed to fully charge the capacitor until the end of the sleep mode period based on the capacitor size and the measured current;
Agree a minimum extended time slot duration with the static device to fully charge the capacitor with the measured current until the end of each sleep mode period, if the determined charge time needed is longer than the duration of the sleep mode period between ranging rounds.

2. Method according to claim 1, wherein the minimum extended time slot duration is agreed with the static device to fully charge the capacitor with the measured current until the end of each sleep mode period, if the determined charge time needed is longer than the duration of the sleep mode period between ranging rounds and at least one idle mode period, in between the transmission of ranging frames of one ranging round.

3. Method according to claim 1, wherein the determination of the charge time needed in addition takes a measured temperature in the wearable device into account.

4. Method according to claim 1, wherein the determination of the charge time needed in addition takes the capacitor load or capacitor voltage left in the capacitor at the end of the ranging round into account.

5. Method according to claim 1, wherein the wearable device communicates and agrees with the static device on the shortest time slot duration possible for the static device to set an initial time slot duration, before the recurring steps in wearable device are processed.

6. Method according to claim 1, wherein a smart key is used as wearable device to open a door of a vehicle used as static device.

7. Method according to claim to 6, wherein the communication between the smart key and the vehicle to agree the minimum changed time slot duration is based on a technical specification of the Car Connectivity Consortium, in particular on the Digital Key Release 3 technical specification.

8. System of a wearable device powered by a battery and built to emit a digital pulse signal and a static device built to process a multilateration of the wearable device, wherein the static device comprises:
at least two receivers, both built to receive the digital pulse signal with a time difference caused by their individual distance to the wearable device;
a multilateration stage built to process a multilateration of the wearable device based on the time difference between the two received digital pulse signals;
a static device communication stage built to communicate commands and/or data with the wearable device,
and wherein the wearable device comprises:
a transmitter stage built to transmit the digital pulse signal composed of several ranging rounds, each with a sequence of digital pulses, and sleep mode periods without digital pulses between the ranging rounds,
a measurement stage built to measure a current provided by the battery of the wearable device to a capacitor of the wearable device, which capacitor is dimensioned that its capacitor load of the fully charged capacitor powers the wearable device during one ranging round;
a determination stage built to determine a charge time needed to fully charge the capacitor until the end of the sleep mode period based on the capacitor size and the measured current;
a wearable device communication stage built to communicate a request for a minimum extended time slot duration with the static device communication stage to fully charge the capacitor with the measured current until the end of each sleep mode period, if the determined charge time needed is longer than the duration of the sleep mode period between ranging rounds.

9. System according to claim 8, wherein the wearable device communication stage built to communicate a request for the minimum extended time slot duration with the static device communication stage to fully charge the capacitor with the measured current until the end of each sleep mode period, if the determined charge time needed is longer than the duration of the sleep mode period between ranging rounds and at least one idle mode period, in between the transmission of ranging frames of one ranging round.

10. System according to claim 8, wherein the measurement stage is built to measure the temperature in the wearable device and wherein the determination stage is built to further take the measured temperature into account to determine the charge time needed.

11. System according to claim 8, wherein the wearable device comprises a current limiter to limit the current provided by the battery to the capacitor.

12. System according to claim 8, wherein the transmitter stage is built to transmit the digital pulse signal in the 3.1 GHz to 10.61 GHz band and/or wherein the static device communication stage and the wearable device communication stage are built to communicate in the 2.4 GHz to 2.4835 GHz band.

13. Smart key built to open a door of a vehicle, which smart key comprises the features of the wearable device according to the system of claim 8.
